(19) United States
(12) Patent Application Publication
(10) Pub. No.: US 2026/0223526 A1
(43) Pub. Date: Jul. 30, 2026

(54) Quantum Dot, Electronic Apparatus and Electronic Equipment Including the Quantum Dot, and Method of Preparing Quantum Dot

(71) Applicant: Samsung Display Co., Ltd., Yongin-si (KR)

(72) Inventors: Seungwon Park, Yongin-si (KR); Sungjae Kim, Yongin-si (KR); Youngsik Kim, Yongin-si (KR); Hongrae Kim, Yongin-si (KR); Juo Nam, Yongin-si (KR); Bitna Yoon, Yongin-si (KR); Taekjoon Lee, Yongin-si (KR); Junehyuk Jung, Yongin-si (KR)

(73) Assignee: Samsung Display Co., Ltd., Yongin-si (KR)

(21) Appl. No.: 19/451,098

(22) Filed: Jan. 16, 2026

(30) Foreign Application Priority Data
Jan. 24, 2025 (KR) 10-2025-0011881

(51) Int. Cl. H10K 50/115; C09K 11/62; C09K 113/00

(52) U.S. Cl. CPC H10K 50/115; C09K 11/623; C09K 2113/00

(57) ABSTRACT

A quantum dot may include a core including copper (Cu), a Group III element, and a Group VI element, and a shell covering the core and including zinc (Zn) and a Group VI element, wherein an atomic ratio of Zn/Cu is in a range of about 1 to about 4.

### CROSS-REFERENCE TO RELATED APPLICATION

This application claims priority under 35 U.S.C. § 119 to Korean Patent Application No. 10-2025-0011881, filed on Jan. 24, 2025, in the Korean Intellectual Property Office, the disclosure of which is incorporated by reference herein in its entirety.

### TECHNICAL FIELD

Aspects of the present disclosure relate to a quantum dot, an electronic apparatus and electronic equipment that include the quantum dot, and a method of preparing the quantum dot.

### BACKGROUND

Quantum dots are nano-sized semiconductor nanocrystals that exhibit the quantum confinement effect, and by controlling the size and composition of the nanocrystals, the quantum dots may have different energy bandgaps, and may therefore emit light of various emission wavelengths.

Such quantum dots may be used in a variety of optical components and electronic apparatuses, and there is a need for quantum dots with a narrow full width at half maximum in luminescence and excellent quantum efficiency at desired wavelengths.

### SUMMARY

One or more aspects include a quantum dot having a narrow full width at half maximum in luminescence and excellent quantum efficiency.

Additional aspects will be set forth in part in the description which follows and, in part, will be apparent from the description, or may be learned by practice of the presented aspects of the disclosure.

According to one or more aspects, a quantum dot includes a core comprising copper (Cu), a Group III element, and a Group VI element, and a shell covering the core and comprising zinc (Zn) and a Group VI element, wherein an atomic ratio of Zn/Cu is in a range of about 1 to about 4.

The Group VI element may include sulfur (S), selenium (Se), tellurium (Te), or any combination thereof.

The Group III element may include aluminum (Al), gallium (Ga), indium (In), thallium (Tl), or any combination thereof.

The core may include Cu, In, Ga, and S.

In an aspect, the quantum dot may further include an intermediate shell arranged between the core and the shell and including a Group III element and a Group VI element, wherein a composition of the intermediate shell may be different from a composition of the core.

The core may have a diameter in a range of about 1 nm to about 10 nm, and the shell may have a thickness in a range of about 0.1 nm to about 2 nm.

A full width at half maximum of a photoluminescence spectrum of the quantum dot may be 50 nm or less.

In an aspect, the quantum dot may be a CuInGaS₂/ZnS core shell quantum dot.

According to one or more aspects, an electronic apparatus includes a light source, and a color conversion member arranged in a path of light emitted from the light source, wherein the color conversion member includes the quantum dot.

According to one or more aspects, electronic equipment includes the electronic apparatus.

According to one or more aspects, a method of preparing the quantum dot includes synthesizing a seed including copper (Cu) and a Group VI element, synthesizing a core by reaction between the seed and a precursor of a Group III element, and forming a shell on the core by reaction between a solution of the core and a zinc (Zn) precursor.

The Group VI element may include sulfur (S), selenium (Se), tellurium (Te), or any combination thereof.

The Group III element may include aluminum (Al), gallium (Ga), indium (In), thallium (Tl), or any combination thereof.

In an aspect, the seed may be Cu₂₋ₓS (0≤x≤1.5).

In an aspect, the core may include Cu, In, Ga, and S.

In an aspect, the solution of the core may be a solution in which the reaction between the seed and the precursor of the Group III element occurs.

The core may have a diameter in a range of about 1 nm to about 10 nm.

The shell may have a thickness in a range of about 0.1 nm to about 2 nm.

The quantum dot may have an atomic ratio of Zn/Cu in a range of about 1 to about 4.

### BRIEF DESCRIPTION OF THE DRAWINGS

The above and other features and advantages of certain aspects of the disclosure will be more apparent from the following description taken in conjunction with the accompanying drawings, in which:

FIG. 1 is a schematic cross-sectional view of a quantum dot according to an aspect;

FIG. 2 is a flowchart illustrating a method of preparing a quantum dot, according to an aspect;

FIG. 3 is a schematic view showing a structure of an electronic apparatus according to an aspect;

FIG. 4 is a schematic view of a structure of a light-emitting apparatus as an example of an electronic apparatus according to an aspect;

FIG. 5 is a block diagram of electronic equipment according to an aspect;

FIG. 6 is a schematic view of electronic equipment according to various aspects;

FIG. 7 is a schematic perspective view of electronic equipment including a light-emitting device according to an aspect;

FIG. 8 is a diagram illustrating the exterior of a vehicle as electronic equipment including a light-emitting device according to an aspect;

FIGS. 9A to 9C are each a diagram schematically illustrating the interior of a vehicle according to various aspects;

FIGS. 10A to 10C are each a transmission electron microscopy (TEM) image of a Cu₂₋ₓS seed, a CuInGaS₂ core, and a CuInGaS₂/ZnS core/shell, respectively, as prepared in Example 1; and

FIG. 11 is a graph showing a photoluminescence spectrum of a quantum dot of Example 1.

### DETAILED DESCRIPTION

Reference will now be made in detail to aspects of the present disclosure, examples of which are illustrated in the accompanying drawings, wherein like reference numerals refer to like elements throughout. In this regard, the present aspects may have different forms and should not be construed as being limited to the descriptions set forth herein. Accordingly, the aspects are merely described below, by referring to the figures, to explain technical features of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present disclosure allows for various changes and numerous aspects, exemplary aspects will be illustrated in the drawings and described in detail in the written description. An effect and a characteristic of the disclosure, and a method of accomplishing these will be apparent when referring to aspects described with reference to the drawings. The disclosure may, however, be embodied in many different forms and should not be construed as limited to the aspects set forth herein.

It will be understood that although the terms “first,” “second,” etc. used herein may be used herein to describe various components, these components should not be limited by these terms. These components are only used to distinguish one component from another.

An expression used in the singular encompasses the expression of the plural, unless it has a clearly different meaning in the context.

In the present specification, it is to be understood that the terms such as “including,” “having,” and “comprising” are intended to indicate the existence of the features or components disclosed in the specification, and are not intended to preclude the possibility that one or more other features or components may exist or may be added. For example, unless otherwise limited, terms such as “including” or “having” may refer to either consisting of features or components described in the specification only or further including other components.

The term “Group I” as used herein may include a Group IA element and a Group IB element on the IUPAC periodic table, and the Group I element may include, for example, silver (Ag), copper (Cu), or the like.

The term “Group II” as used herein may include a Group IIA element and a Group IIB element on the IUPAC periodic table, and the Group II element may include, for example, magnesium (Mg), calcium (Ca), zinc (Zn), cadmium (Cd), mercury (Hg), or the like.

The term “Group III” as used herein may include a Group IIIA element and a Group IIIB element on the IUPAC periodic table, and the Group III element may include, for example, aluminum (Al), gallium (Ga), indium (In), thallium (Tl), or the like.

The term “Group VI” as used herein may include a Group VIA element and a Group VIB element on the IUPAC periodic table, and the Group VI element may include, for example, oxygen (O), sulfur (S), selenium (Se), tellurium (Te), or the like.

### [Quantum Dot]

A quantum dot according to an aspect may include: a core including Cu, a Group III element, and a Group VI element; and a shell covering the core and including Zn and a Group VI element.

An atomic ratio of Zn/Cu in the quantum dot may be in a range of about 1 to about 4. The atomic ratio of Zn/Cu in the quantum dot may be, for example, in a range of about 1.5 to about 4 or about 1.7 to about 3.8. The atomic ratio of Zn/Cu in the quantum dot refers to a compositional ratio of Zn and Cu included in both the core and the shell. The smaller atomic ratio of Zn to Cu indicates a larger content of the core in the quantum dot, and the thinner the shell is formed, the larger the content of the core in the quantum dot.

In addition, the core of the quantum dot according to an aspect may be synthesized by using Cu-containing seeds, and in this regard, the content ratio of Cu in the core may be increased, which may reduce the atomic ratio of Zn/Cu. The light absorption of the quantum dot may occur in the core of the quantum dot, and as the content of the core in the quantum dot increases, the light absorption rate of the quantum dot may be improved. In addition, the core synthesized by using seeds having uniform sizes may exhibit uniform-sized distribution, such that the quantum dot according to an aspect may have a narrow full width at half maximum of a photoluminescence spectrum of 50 nm or less.

The Group VI element may include S, Se, Te, or any combination thereof.

The Group III element may include Al, Ga, In, Tl, or any combination thereof.

In an aspect, the core may include Cu, In, Ga, and S. For example, the core may be CuInGaS₂.

The shell may be, for example, ZnS, ZnSe, ZnTe, ZnSeS, ZnSeTe, ZnSTe, or any combination thereof.

In an aspect, the quantum dot may further include, between the core and the shell, an intermediate shell including the Group III element and the Group VI element, wherein a composition of the intermediate shell may be different from a composition of the core. In an aspect, the intermediate shell may include Cu, Ga, and S. For example, the intermediate shell may be CuGaS₂.

In an aspect, the quantum dot may be a CuInGaS₂/ZnS quantum dot or a CuInGaS₂/CuGaS₂/ZnS quantum dot.

A full width at half maximum of a photoluminescence spectrum of the quantum dot may be 50 nm or less.

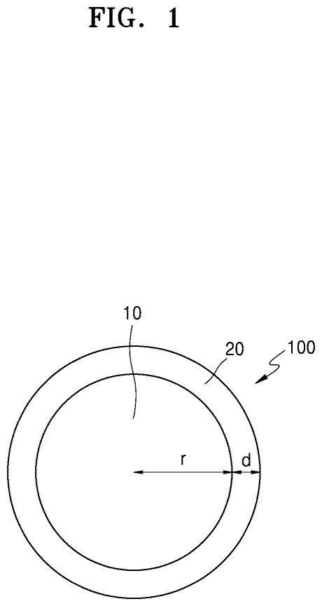

FIG. 1 is a schematic cross-sectional view of a quantum dot 100 according to an aspect. The quantum dot 100 includes a core 10 and a shell 20 surrounding the core 10. The core 10 may have a radius r in a range of about 1 nm to about 10 nm, about 2 nm to about 8 nm, or about 3 nm to about 7 nm. The shell 20 may have a thickness d in a range of about 0.1 nm to about 2 nm, about 0.5 nm to about 2 nm, or about 1 nm to about 2 nm.

In an aspect, an organic ligand may be bonded to the surface of the quantum dot. The organic ligand may include, for example, fatty acids, such as palmitic acid, stearic acid, oleic acid, etc., amines having a hydrocarbon chain, such as oleylamine, trioctylamine, etc., or thiols, such as decanethiol, etc.

Each element included in the quantum dot may be present in a particle at a uniform concentration or non-uniform concentration. For example, a composition of compounds in the core of the quantum dot may not be the same throughout the core, but may vary gradually. In addition, a composition of compounds in the shell of the quantum dot may not be the same throughout the shell, but may vary gradually. For example, the proportion of In may be high in the center of the core, whereas the proportion of Ga may be high in the outer part of the core. In an aspect, the shell may be formed in multiple layers.

In an aspect, the quantum dot may be in the form of nanoparticles, nanotubes, nanowires, nanofibers, or nanoplate in a spherical, pyramidal, multi-armed, or cubic shape.

In an aspect, the quantum dot may be in a spherical shape.

In an aspect, a maximum emission wavelength of a photoluminescence (PL) spectrum of the quantum dot may be in a range of about 490 nm to about 570 nm or about 510 nm to about 550 nm. In an aspect, the maximum emission wavelength of the PL spectrum of the quantum dot may be in a range of about 600 nm to about 760 nm or about 610 nm to about 650 nm. In an aspect, the emission wavelength of the quantum dot may be controlled by the compositional ratio of the core of the quantum dot.

In an aspect, the quantum dot may have photoluminescence quantum efficiency in a range of about 60% to about 98%, about 80% to about 97%, about 85% to about 95%, or about 88% to about 95%.

In an aspect, the quantum dot may have a full width of half maximum (FWHM) of 50 nm or less, for example, in a range of about 30 nm to about 50 nm, in a photoluminescence spectrum. When the FWHM of the quantum dot is within these ranges, the quantum dot may have improved color purity or improved color reproducibility. In addition, since light emitted by the quantum dot is emitted in all directions, the quantum dot may have an improved wide viewing angle.

### [Method of Preparing Quantum Dot]

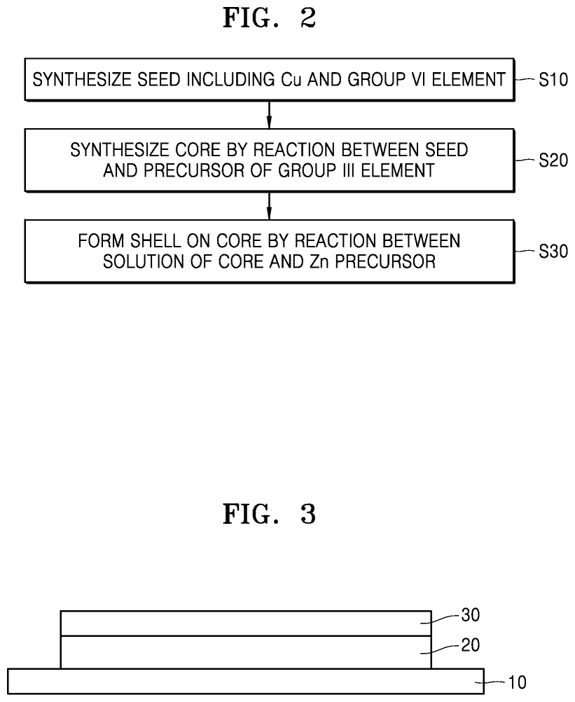

FIG. 2 is a flowchart illustrating a method of preparing the quantum dot, according to an aspect.

Referring to FIG. 2, first, a seed containing Cu and a Group VI element are synthesized (S10). A Cu precursor solution may be injected into a precursor solution of the Group VI element, and by reaction between a Cu precursor and a precursor of the Group VI element, a seed of a Cu-Group VI compound containing Cu and the Group VI element may be synthesized.

The Group VI element may include S, Se, Te, or any combination thereof. For example the seed may be Cu₂₋ₓS (0≤x≤1.5), Cu₂₋ₓSe (0≤x≤1.5), or Cu₂₋ₓTe (0≤x≤1.5).

The Cu precursor solution may be prepared by reaction between a Cu halide and a solvent. The Cu halide may be, for example, CuF, CuCl, CuBr, CuI, or a combination thereof. The solvent may be, for example, a mixed solvent of oleylamine and oleic acid.

The precursor solution of the Group VI element may be prepared by reaction between the Group VI element and a solvent. The solvent may be, for example, octadecene.

The seed thus synthesized may be uniform in size and shape.

Subsequently, by causing a reaction between the seed and the precursor solution of the Group III element, a core may be synthesized (S20).

The precursor solution of the Group III element may be prepared by dissolving the precursor of the Group III element in a solvent and degassing. The Group III element may include Al, Ga, In, Tl, or any combination thereof. In an aspect, the precursor of the Group III element may include an In precursor or a Ga precursor. The In precursor may be, for example, an In halide. The Ga precursor may be, for example, a Ga halide. The In halide may be InF, InCl, InBr, InI, or a combination thereof. The Ga halide may be GaF, GaCl, GaBr, Gal, or a combination thereof. In an aspect, the precursor of the Group III element may further include an organic acid of the Group III element. For example, the precursor of the Group III element may further include indium lauric acid, indium myristic acid, indium palmitic acid, or the like. The solvent may be, for example, a mixed solvent of oleylamine and 1-octadecene.

In an aspect, the seed reacting with the precursor of the Group III element may be a seed solution. In an aspect, the seed solution may be a reaction solution of the Cu precursor and the precursor of the Group VI element that have completed the seed synthesis. In one or more aspects, the seed solution may be a solution in which the seed has been synthesized, purified, and re-dispersed in a solvent.

In an aspect, the core may be synthesized by injecting the seed solution into the precursor solution of the Group III element to cause a reaction with an additionally added precursor of the Group VI element. The precursor of the Group VI element may include, for example, 1-dodecanethiol (1-DDT), S-oleylamine, 1-octanethiol (1-OTT), or a combination thereof. S-oleylamine may be prepared by mixing S with oleylamine.

In an aspect, the core may include Cu, In, Ga, and S. For example, the core may be CuInGaS₂.

The core may have, for example, a diameter in a range of about 1 nm to about 10 nm.

The core synthesized using the seed of uniform size and shape may have a uniform size and shape, as the seed has.

Subsequently, by causing a reaction between a solution of the core and a Zn precursor solution, a shell may be formed (S30).

The solution of the core may be a reaction solution of the seed and the precursor of the Group III element that have completed the core synthesis.

The Zn precursor solution may be prepared by reaction between a Zn precursor and a solvent. In an aspect, the Zn precursor may be a Zn halide. The Zn precursor may be, for example, ZnF₂, ZnCl₂, ZnBr₂, ZnI₂, or a combination thereof. The solvent may be, for example, trioctylphosphine (TOP), acetone, or a combination thereof.

The shell may be formed thinly by lowering the concentration of the S and Zn precursors remaining in the reaction solution of the core. The shell may have a thickness in a range of about 0.1 nm to about 2 nm.

In the quantum dot synthesized according to an aspect, the atomic ratio of Zn to Cu may be in a range of about 1 to about 4.

In an aspect, the method may further include forming an intermediate shell before the forming of the shell. The intermediate shell may include Cu, a Group III element, and a Group VI element, and may have a composition different from that of the core. For example, the intermediate shell may be CuGaS₂. In one or more aspects, the intermediate shell may be a shell not including Cu, but including a Group III element and a Group VI element. For example, the intermediate shell may be GaSₓ (0≤x≤1), InSₓ (0≤x≤1), or InGaSₓ (0≤x≤1).

For a description of the quantum dot synthesized according to an aspect, reference may be made to the aforementioned quantum dot.

Since energy band gaps may be adjusted by controlling the size and shape of the quantum dot, light having various wavelength bands may be obtained from an emission layer including the quantum dots. Accordingly, by using quantum dots of different sizes, a light-emitting device that emits light of various wavelengths may be implemented. In an aspect, the size of the quantum dot may be selected to emit red light, green light, and/or blue light. In addition, the size of the quantum dot may be configured to emit white light by combination of light of various colors.

### [Quantum Dot Composition]

In an aspect, there is provided a quantum dot composition including the quantum dot. The quantum dot composition may be a solvent-free quantum dot composition.

The quantum dot composition may include the aforementioned quantum dot and a polymerizable monomer (e.g., a photopolymerizable monomer). An organic ligand may be bonded to the surface of the quantum dot as described above.

For use as the polymerizable monomer, any polymerizable monomer commonly used in the art may be used. In an aspect, the polymerizable monomer may include a (meta)acrylate-based monomer. In the present disclosure, the term “(meth)acrylate” refers to an acrylate or a methacrylate. For example, the (meth)acrylate-based monomer may include a (meth)acryl group or acryloyl group, at least one of a vinyl group and an allyl group. The (meth)acrylate-based monomer may be, for example 1,6-hexanediol diacrylate, 1,6-cyclohexanediol diacrylate, 2,2-dimethyl-1,3-propanediol diacylate, diethylene glycol diacrylate, dipropylene glycol diacrylate, 1,3-butylene glycol dimethacrylate, trimethylolpropane trimethacrylate, isobonyl acrylate, isobonyl methacrylate, tetrahydrofuryl acrylate, acryloyl morpholine, 2-phenoxyethyl acrylate, tripropylene glycol diacrylate, trimethylolpropane triacrylate, pentaerythritol mono(meth)acrylate, pentaerythritol di(meth)acrylate, pentaerythritol triacrylate, pentaerythritol trimethacrylate, dipentaerythritol hexaacrylate, dipentaerythritol hexamethacrylate, or a combination thereof.

The quantum dot may further include a photoinitiator. The photoinitiator may be excited by a light source such as ultraviolet ray (UV) to initiate photopolymerization of the polymerizable monomer, and any photoinitiator commonly used in the art may be used. In an aspect, the photoinitiator may be an acetophenone-based compound, a benzophenone-based compound, a thioxanthone-based compound, a benzoin-based compound, a triazine-based compound, or an oxim-based compound.

The photoinitiator may be, for example, ethyl(2,4,6-trimethylbenzoyl)phenylphosphinate, Irgacure 184, Irgacure 369, Irgacure 651, Irgacure 819, Irgacure 907, benzionalkylether, benzophenone, benzyl dimethyl katal, hydroxycyclohexyl phenyl acetone, chloroacetophenone, 1,1-dichloro acetophenone, diethoxy acetophenone, hydroxy acetophenone, 2-chloro thioxanthone, 2-ethylanthraquinone (2-ETAQ), 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, methylbenzoylformate, or a combination thereof.

In an aspect, the quantum dot composition may further include a light diffuser. The light diffuser may increase the amount of light absorbed by the quantum dot by reflecting light that is not absorbed by the quantum dot and allowing the reflected light to be absorbed again by the quantum dot, thereby increasing the light conversion efficiency.

For use as the light diffuser, any light diffuser commonly used in the art may be used. For example, the light diffuser may include barium sulfate (BaSO₄), calcium carbonate (CaCO₃), titanium dioxide (TiO₂), zirconia (ZrO₂), or a combination thereof. The average particle diameter or shape of the light diffuser are not particularly limited, and may be appropriately selected. For example, the average particle diameter D50 of the light diffuser may be in a range of about 150 nm to about 250 nm, for example, about 180 nm to about 230 nm.

In an aspect, the amount of the quantum dot may be, based on the total weight of the quantum dot composition, in a range of about 1 wt % to about 60 wt %, about 10 wt % to about 55 wt %, or about 20 wt % to about 50 wt %.

In an aspect, the amount of the polymerizable monomer may be, based on the total weight of the quantum dot composition, in a range of about 35 wt % to about 80 wt %, about 40 wt % to about 75 wt %, or about 45 wt % to about 70 wt %.

In an aspect, the amount of the photoinitiator may be, based on the total weight of the quantum dot composition, in a range of about 0.01 wt % to about 10 wt %, about 0.05 wt % to about 7 wt %, or about 0.1 wt % to about 5 wt %.

In an aspect, the amount of the light diffuser may be, based on the total weight of the quantum dot composition, in a range of about 0.01 wt % to about 10 wt %, about 0.05 wt % to about 7 wt %, or about 0.1 wt % to about 5 wt %.

The quantum dot composition including the quantum dot according to an aspect may have excellent luminescence properties and excellent quantum efficiency, and thus by using the quantum dot composition, high-quality optical members, electronic apparatuses, and electronic equipment may be provided.

### [Electronic Apparatus]

The quantum dot may be used in various electronic apparatuses. Accordingly, there is provided an electronic apparatus including the quantum dot.

In an aspect, the electronic apparatus may include: a light source; and a color conversion member arranged in an optical path of light emitted from the light source, wherein the color conversion member includes the quantum dot.

### [Description of FIG. 3]

FIG. 3 is a schematic view showing a structure of the electronic apparatus according to an aspect. The electronic apparatus of FIG. 3 includes: a substrate 10; a light source 20 arranged on the substrate 10; and a color conversion member 30 arranged on the light source 20.

For example, the light source 20 may be an inorganic light-emitting device, an organic light-emitting device, a quantum dot light-emitting device (QLED), or any combination thereof. The color conversion member 30 may be arranged in at least one direction of travel of light emitted from the light source 20.

At least one area of the color conversion member 30 of the electronic apparatus may include the quantum dot, and the area may absorb light emitted from the light source 20 to emit green light or red light having a maximum emission wavelength in a range of 495 nm to about 750 nm.

Here, a case where the color conversion member 30 is arranged in at least one direction of travel of the light emitted from the light source 20 does not exclude that other elements may be further included between the color conversion member 30 and the light source 20.

The electronic apparatus of FIG. 3, which is an example of a device according to an aspect, may have various forms known in the art, and for this purpose, may further include various configurations known in the art.

In an aspect, the color conversion member 30 may further include a color filter.

The color filter may include a pigment or a dye.

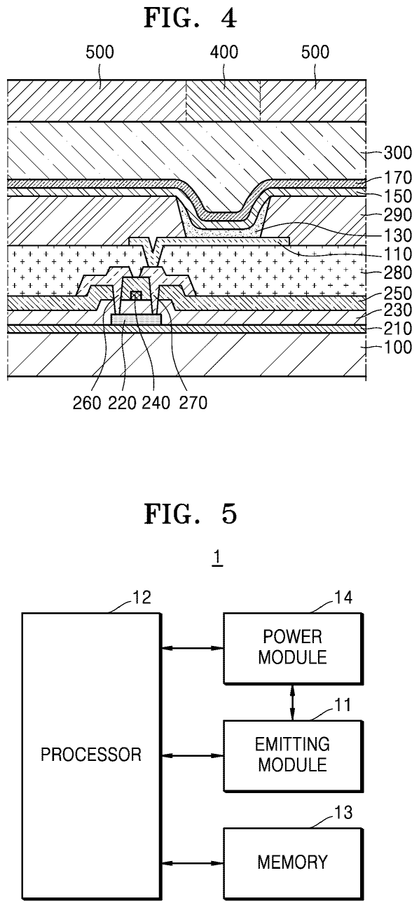

### [Description of FIG. 4]

FIG. 4 is a schematic view of a structure of a light-emitting apparatus as an example of the electronic apparatus according to an aspect.

The light-emitting apparatus of FIG. 4 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100, and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating layer 230 for insulating the active layer 220 from the gate electrode 240 may be arranged on the active layer 220, and the gate electrode 240 may be arranged on the gate insulating layer 230.

An interlayer insulating layer 250 may be arranged on the gate electrode 240. The interlayer insulating layer 250 may be arranged between the gate electrode 240 and the source electrode 260 and between the gate electrode 240 and the drain electrode 270, to insulate from one another.

The source electrode 260 and the drain electrode 270 may be arranged on the interlayer insulating layer 250. The interlayer insulating layer 250 and the gate insulating layer 230 may be formed to expose the source region and the drain region of the active layer 220, and the source electrode 260 and the drain electrode 270 may be arranged in contact with the exposed portions of the source region and the drain region of the active layer 220.

The TFT may be electrically connected to the light-emitting device to drive the light-emitting device, and may be covered and protected by a passivation layer 280. The passivation layer 280 may include an inorganic insulating layer, an organic insulating layer, or any combination thereof. The light-emitting device may be provided on the passivation layer 280. The light-emitting device may include the first electrode 110, the interlayer 130, and the second electrode 150. The interlayer 130 may include an emission layer. In an aspect, the emission layer may include an organic luminescent material. In one or more aspects, the emission layer may include a quantum dot-luminescent material. The quantum dot-luminescent material may be the aforementioned quantum dot. The interlayer 130 may further include a hole transport layer between the first electrode 110 and the emission layer and an electron transport layer between the second electrode 150 and the emission layer.

The first electrode 110 may be arranged on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel defining layer 290 including an insulating material may be arranged on the first electrode 110. The pixel defining layer 290 may expose a certain region of the first electrode 110, and an interlayer 130 may be formed in the exposed region of the first electrode 110. The pixel defining layer 290 may be a polyimide-based organic layer or a polyacrylic-based organic layer. Although not shown in FIG. 4, at least some layers of the interlayer 130 may extend beyond the upper portion of the pixel defining layer 290 to be arranged in the form of a common layer.

The second electrode 150 may be arranged on the interlayer 130, and a second capping layer 170 may be additionally formed on the second electrode 150. The second capping layer 170 may be formed to cover the second electrode 150.

The encapsulation portion 300 may be arranged on the second capping layer 170. The encapsulation portion 300 may be arranged on the light-emitting device to protect the light-emitting device from moisture or oxygen. The encapsulation portion 300 may include: an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or any combination thereof, or any combination of the inorganic layers and the organic layers.

A light-shielding pattern 500 and a functional region 400 may be arranged on the encapsulation portion 300. The functional region 400 may be i) a color filter area, ii) a color conversion area, or iii) a combination of the color filter area and the color conversion area. In an aspect, the color conversion region may include the aforementioned quantum dot. In an aspect, the light-emitting device included in the light-emitting apparatus of FIG. 4 may be a tandem light-emitting device.

Various functional layers other than the color filter and/or the color conversion layer may be additionally arranged on the encapsulation portion 300 according to the purpose of the electronic apparatus. Examples of the functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the aforementioned light-emitting apparatus, a biometric information collector.

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

### [Optical Member]

The quantum dot may be used in various optical members. Accordingly, there is provided an optical member including the quantum dot.

In an aspect, the optical member may be a light control means.

In one or more aspects, the optical member may be a color filter, a color conversion member, a capping layer, a light-extraction efficiency enhancement layer, a selective light-absorption layer, or a polarizing layer.

### [Electronic Equipment]

The quantum dot and the electronic apparatus including the quantum dot may be included in various types of electronic equipment.

For example, the electronic equipment including the light-emitting apparatus may be one of a flat panel display, a curved display, a computer monitor, a medical monitor, a television, a billboard, a light for indoor or outdoor lighting and/or signaling, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including multiple displays tiled together, a theater screen, a stadium screen, a phototherapy device, or a signboard.

The light-emitting device has excellent effects in terms of luminescence efficiency and long lifespan, and thus the electronic equipment including the light-emitting apparatus including the light-emitting device may have characteristics, such as high luminance, high resolution, and low power consumption.

### [Description of FIG. 5]

FIG. 5 is a block diagram of electronic equipment 1 according to an aspect. Referring to FIG. 5, the electronic equipment 1 according to an aspect includes a light-emitting module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for the operation of the processor 12 or the light-emitting module 11 may be stored in the memory 13. When the processor 12 executes an application stored in the memory 13, an image data signal and/or an input control signal is transmitted to the light-emitting module 11, and the light-emitting module 11 may process the received signal and output image information through a display screen.

The power module 14 may include: a power supply module, such as a power adapter or a battery device; and a power conversion module that converts power supplied by the power supply module to generate power required for the operation of the electronic equipment 1.

At least one of components of the electronic equipment 1 may be included in the light-emitting apparatus according to the aforementioned aspects. In addition, some of individual modules functionally included in a single module may be included in the light-emitting apparatus, and others may be provided separately from the light-emitting apparatus. For example, the light-emitting apparatus may include the light-emitting module 11, and the processor 12, the memory 13, and the power module 14 may be provided in the form of other devices within the electronic equipment 1 other than the light-emitting apparatus.

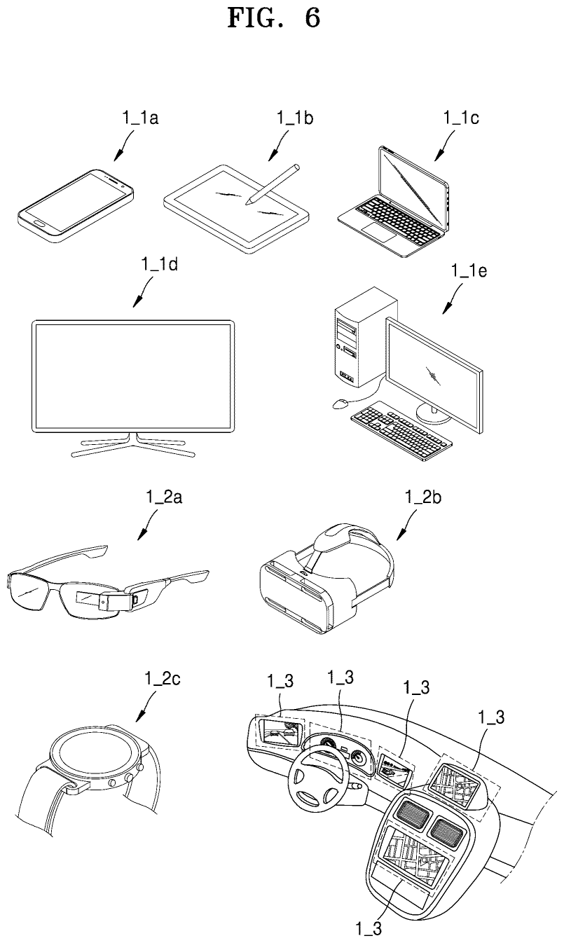

### [Description of FIG. 6]

FIG. 6 is a schematic view of the electronic equipment according to various aspects.

Referring to FIG. 6, various types of electronic equipment to which an electronic apparatus (e.g., a light-emitting apparatus) is applied may include not only electronic equipment for displaying images, such as a smart phone 1_1a, a tablet PC 1_1b, a laptop 1_1c, a TV 1_1d, a desktop monitor 1_1e, etc., but also wearable electronic equipment including a light-emitting module, such as smart glasses 1_2a, a head-mounted display 1_2b, a smart watch 1_2c, etc., or vehicle electronic equipment 1_3 including a light-emitting module, such as an automobile dashboard, a center fascia, a center information display (CID) on a dashboard, a room mirror display, etc.

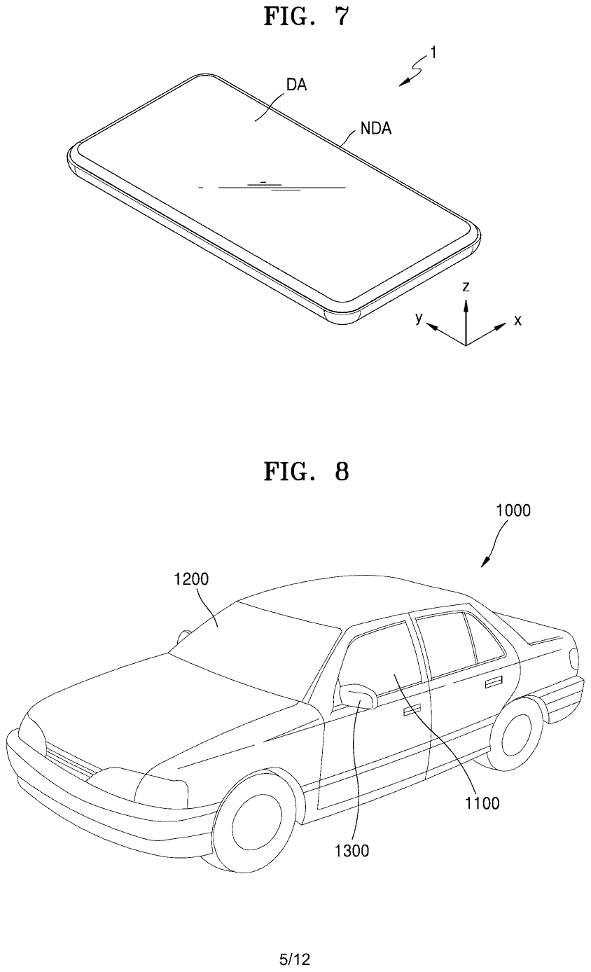

### [Description of FIG. 7]

FIG. 7 is a schematic perspective view of the electronic equipment 1 including the light-emitting device according to an aspect. The electronic equipment 1 may be, as an apparatus that displays a moving image or a still image, portable electronic equipment, such as a mobile phone, a smart phone, a tablet personal computer (PC), a mobile communication terminal, an electronic notebook, an electronic book, a portable multimedia player (PMP), a navigation, or a ultra-mobile PC (UMPC), as well as various products or a part thereof, such as a television, a laptop, a monitor, a billboard, or an Internet of things (IOT) display. In addition, the electronic equipment 1 may be a wearable device or a part thereof, such as a smart watch, a watch phone, a glasses-type display, or a head mounted display (HMD). However, aspects of the disclosure are not limited thereto. In an aspect, the electronic equipment 1 may be a dashboard of a vehicle, a CID arranged on a center fascia or dashboard of a vehicle, a room mirror display replacing a side-view mirror of a vehicle, an entertainment display for the back seat of a vehicle, a display arranged on the back of the front seat of a vehicle, a head up display (HUD) installed on the front of a vehicle or projected on a front window glass, or a computer generated hologram augmented reality head up display (CGH AR HUD). FIG. 7 illustrates an aspect in which the electronic equipment 1 is a smart phone for convenience of description.

The electronic equipment 1 may include a display area DA and a non-display area NDA outside the display area DA. A display apparatus may implement an image through an array of a plurality of pixels that are two-dimensionally arranged in the display area DA.

The non-display area NDA is an area that does not display an image, and may entirely surround the display area DA. On the non-display area NDA, a driver for providing electrical signals or power to display apparatuses arranged on the display area DA may be arranged. On the non-display area NDA, a pad, which is an area to which an electronic element or a printing circuit board, may be electrically connected may be arranged.

In the electronic equipment 1, a length in the x-axis direction and a length in the y-axis direction may be different from each other. In an aspect, as shown in FIG. 7, the length in the x-axis direction may be shorter than the length in the y-axis direction. In one or more aspects, the length in the x-axis direction may be the same as the length in the y-axis direction. In one or more aspects, the length in the x-axis direction may be longer than the length in the y-axis direction.

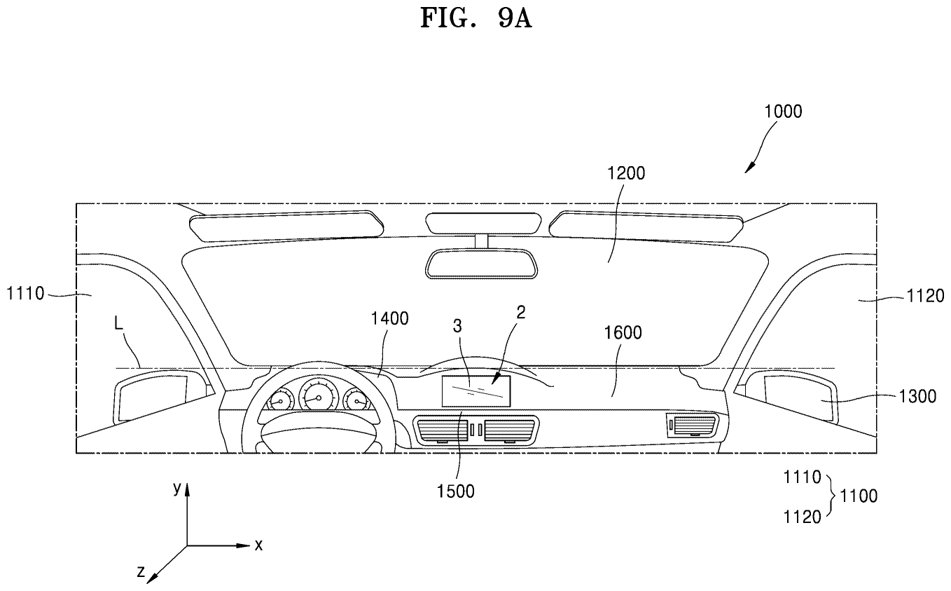

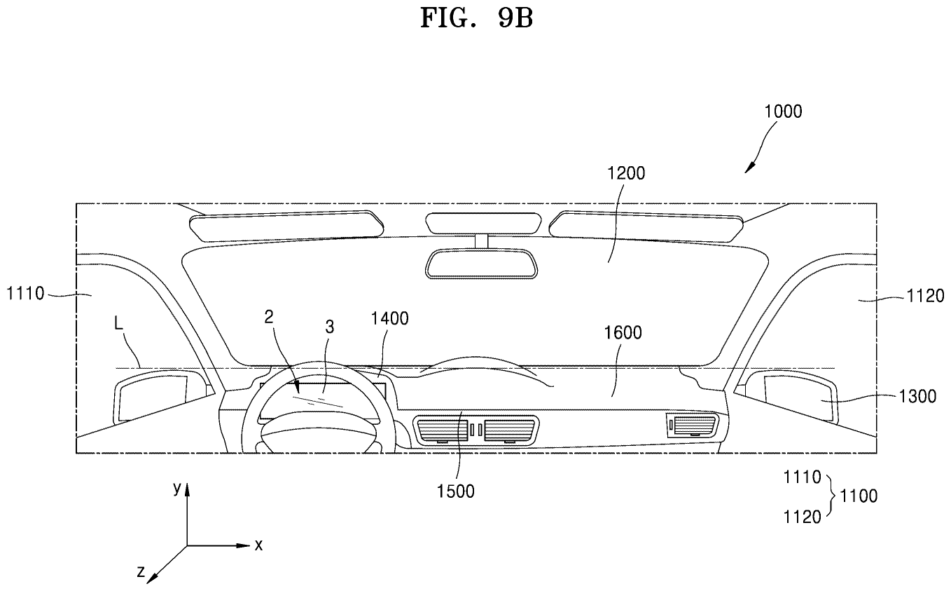

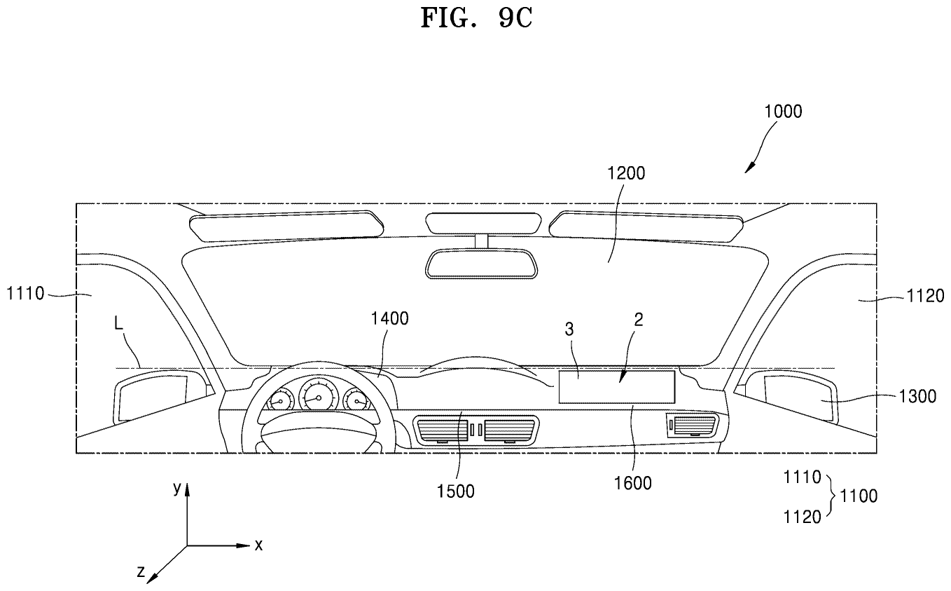

### [Description of FIGS. 8 and 9A to 9C]

FIG. 8 is a diagram illustrating the exterior of a vehicle 1000 as the electronic equipment including a light-emitting device according to an aspect. FIGS. 9A to 9C are each a schematic view of the interior of the vehicle 1000 according to one or more aspects.

Referring to FIGS. 8 and 9A to 9C, the vehicle 1000 may refer to various apparatuses for moving a subject to be transported, such as a human, an object, or an animal, from a departure point to a destination point. The vehicle 1000 may include a vehicle traveling on a road or track, a vessel moving over the sea or river, an airplane flying in the sky using the action of air, and the like.

The vehicle 1000 may travel on a road or a track. The vehicle 1000 may move in a predetermined direction according to rotation of at least one wheel. For example, the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses necessary for driving are installed as other parts except for the body. The exterior of the body may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear wheels, left and right wheels, and the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on the side of the vehicle 1000. In an aspect, the side window glass 1100 may be installed on a door of the vehicle 1000. A plurality of side window glasses 1100 may be provided and may face each other. In an aspect, the side window glass 1100 may include a first side window glass 1110 and a second side window glass 1120. In an aspect, the first side window glass 1110 may be arranged adjacent to the cluster 1400. The second side window glass 1120 may be arranged adjacent to the passenger seat dashboard 1600.

In an aspect, the side window glasses 1100 may be spaced apart from each other in the x-direction or the −x-direction. For example, the first side window glass 1110 and the second side window glass 1120 may be spaced apart from each other in the x direction or the −x direction. In other words, an imaginary straight line L connecting the side window glasses 1100 may extend in the x-direction or the −x-direction. For example, an imaginary straight line L connecting the first side window glass 1110 and the second side window glass 1120 to each other may extend in the x direction or the −x direction.

The front window glass 1200 may be installed in front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In one aspect, a plurality of side mirrors 1300 may be provided. Any one of the plurality of side mirrors 1300 may be arranged outside the first side window glass 1110. The other one of the plurality of side mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning lamp, a seat belt warning lamp, an odometer, an automatic shift selector indicator lamp, a door open warning lamp, an engine oil warning lamp, and/or a low fuel warning light.

The center fascia 1500 may include a control panel on which a plurality of buttons for adjusting an audio device, an air conditioning device, and a heater of a seat are disposed. The center fascia 1500 may be arranged on one side of the cluster 1400.

A passenger seat dashboard 1600 may be spaced apart from the cluster 1400 with the center fascia 1500 arranged therebetween. In an aspect, the cluster 1400 may be arranged to correspond to a driver seat (not shown), and the passenger seat dashboard 1600 may be disposed to correspond to a passenger seat (not shown). In an aspect, the cluster 1400 may be adjacent to the first side window glass 1110, and the passenger seat dashboard 1600 may be adjacent to the second side window glass 1120.

In an aspect, the display apparatus 2 may include a display panel 3, and the display panel 3 may display an image. The display apparatus 2 may be arranged inside the vehicle 1000. In an aspect, the display apparatus 2 may be arranged between the side window glasses 1100 facing each other. The display apparatus 2 may be arranged on at least one of the cluster 1400, the center fascia 1500, and the passenger seat dashboard 1600.

The display apparatus 2 may include an organic light-emitting display apparatus, an inorganic EL display apparatus, a quantum dot display apparatus, and the like. Hereinafter, as the display apparatus 2 according to an aspect, an organic light-emitting display apparatus including the light-emitting device according to the disclosure will be described as an example, but various types of display apparatuses as described above may be used in aspects of the disclosure.

Referring to FIG. 9A, the display apparatus 2 may be arranged on the center fascia 1500. In an aspect, the display apparatus 2 may display navigation information. In an aspect, the display apparatus 2 may display audio, video, or information regarding vehicle settings.

Referring to FIG. 9B, the display apparatus 2 may be arranged on the cluster 1400. When the display apparatus 2 is arranged on the cluster 1400, the cluster 1400 may display driving information and the like through the display apparatus 2. That is, the cluster 1400 may be implemented digitally. The digital cluster 1400 may display vehicle information and driving information as images. For example, a needle and a gauge of a tachometer and various warning light icons may be displayed by a digital signal.

Referring to FIG. 9C, the display apparatus 2 may be arranged on the passenger seat dashboard 1600. The display apparatus 2 may be embedded in the passenger seat dashboard 1600 or arranged on the passenger seat dashboard 1600. In an aspect, the display apparatus 2 arranged on the passenger seat dashboard 1600 may display an image related to information displayed on the cluster 1400 and/or information displayed on the center fascia 1500. In one or more aspects, the display apparatus 2 arranged on the passenger seat dashboard 1600 may display information different from information displayed on the cluster 1400 and/or information displayed on the center fascia 1500.

Hereinafter, methods of preparing the quantum dot according to example aspects will be described in more detail in the Examples below.

### EXAMPLES

### Synthesis of CuInGaS₂ Quantum Dot

### Example 1

### Synthesis of Cu₂₋ₓS Seed

(a) 5 mmol of CuCl, 5 ml of oleylamine (OLA), and 4 ml of oleic acid were added into a three-neck flask and mixed together. The mixed solution was then degassed and stirred at 120° C. for 30 minutes. Next, in a nitrogen (N₂) atmosphere, the temperature was raised to 130° C., and the reaction was allowed for 10 minutes to prepare a Cu precursor solution.
(b) 0.32 g (10 mmol) of sulfur (S) and 40 ml of octadecene were added into a three-neck flask, and mixed together. The mixed solution was then degassed and stirred at 120° C. for 30 minutes. Next, in an N₂ atmosphere, the temperature was raised to 200° C., and the reaction was allowed for 10 minutes. The reaction solution was then cooled to 100° C. to prepare a S precursor solution.
(c) The Cu precursor solution of (a) was injected into the S precursor solution of (b). The mixed solution was allowed for a reaction at 100° C. for 5 minutes, and cooled to room temperature to prepare a Cu₂₋ₓS seed solution.

### Synthesis of CuInGaS₂ Core

(d) 0.6 mmol of InI₃, 1.6 mmol of GaCl₃, 0.3 mmol of indium laurate (In(LA)₃), 20 ml of octadecene, and 10 ml of oleylamine were added into a three-neck flask, and mixed together. The mixed solution was degassed and stirred at 120° C. for 30 minutes to prepare a solution of In and Ga precursors.
(e) 3.1 ml of the Cu₂₋ₓS seed solution of (c) was injected into the solution of (d) at 120° C., and in the N₂ atmosphere, 1.4 ml of dodecanethiol (DDT) and 2 ml of S-oleylamine (a 1.0 M oleylamine solution containing S) were additionally injected thereinto. The temperature was raised to 280° C., and the reaction was allowed for 10 minutes to synthesize a CuInGaS₂ core.

### Synthesis of CuInGaS₂/ZnS Core/Shell

After cooling the CuInGaS₂ core solution of (e) to 240° C., 2.0 mmol of ZnCl₂-TOP (4 ml of a 0.5 M TOP solution containing ZnCl₂) were injected thereinto, and the reaction was allowed for 20 minutes to synthesize a CuInGaS₂/ZnS core/shell quantum dot.

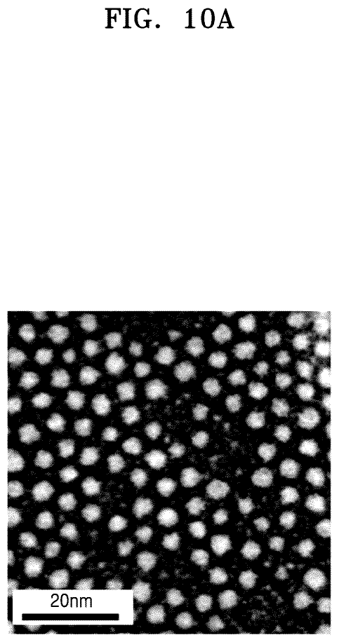

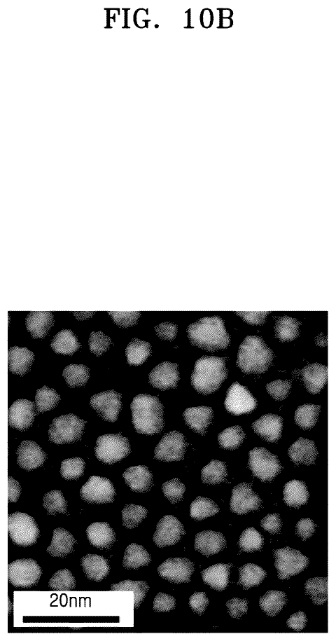

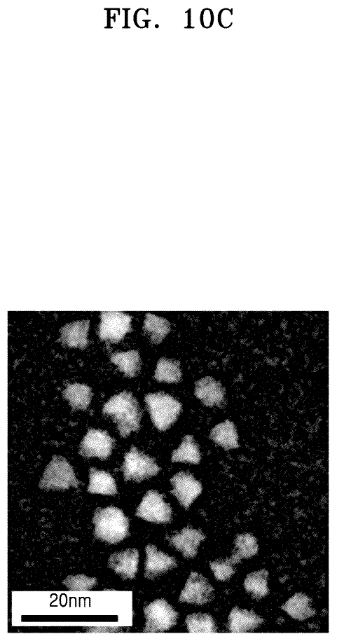

FIGS. 10A to 10C are transmission electron microscopy (TEM) images of the Cu₂₋ₓS seed, the CuInGaS₂ core, and the CuInGaS₂/ZnS core/shell, respectively, as prepared in Example 1. Referring to FIGS. 10A to 10C, it was confirmed that the Cu₂₋ₓS seed was synthesized with uniform size, and the CuInGaS₂ core and the CuInGaS₂/ZnS core/shell quantum dot were synthesized with uniform size based on the Cu₂₋ₓS seed. That is, as the quantum dot of Example 1 was synthesized with uniform size and its surface was stabilized by the shell, the full width at half maximum of a photoluminescence spectrum of the quantum dot may be reduced.

### Comparative Example 1: Synthesis of CuInGaS₂/ZnS Core/Shell (Refer to J. Chem. Phys. 2023, 158, 164708)

### Synthesis of CuInGaS₂ Core

Powders of Cu(OAc)₂, In(acac)₃, and Ga(acac)₃ were mixed in such an amount that the sum of each metal ion was 0.20 mmol, giving an atomic ratio of Cu/(In+Ga)=0.3 and an atomic ratio of In/(In+Ga)=0.7. Using the mixed powders, a CuInGaS₂ core was synthesized by a known single-step heating-up method for synthesis of quantum dots of Cu—In—Ga—S.

### Synthesis of CuInGaS₂/ZnS Core/Shell

10 nmol of the CuInGaS₂ core was added to 3.0 ml of oleylamine (OLA) containing 0.017 mmol of Zn(OAc)₂ and 0.017 mmol of thiourea, and the mixed solution was stirred in a nitrogen atmosphere at 220° C. for 30 minutes. As the solution was cooled to room temperature, a CuInGaS₂ quantum dot coated with ZnS (CuInGaS₂/ZnS) was obtained, subjected to a purification process, and then dissolved in chloroform.

### Comparative Example 2: Synthesis of CuInGaS₂/GaS Core/Shell (Refer to J. Chem. Phys. 2023, 158, 164708)

10 nmol of CuInGaS₂ core, which was synthesized in the same manner as in Comparative Example 1, was added to 3.0 ml of OLA containing 0.010 mmol of Ga(DDTC)₃ and 0.030 mmol of Ga(acac)₃, and the mixed solution was stirred in a nitrogen atmosphere at 250° C. for 30 minutes. As the solution was cooled to room temperature, a CuInGaS₂ quantum dot coated with GaSₓ (CuInGaS₂/GaSₓ) was obtained, subjected to a purification process, and then dissolved in chloroform. (Ga(DDTC)₃: gallium N,N-diethyldithiocarbamate)

### Comparative Example 3: Synthesis of CuInGaS₂/GaZnS Core/Shell (Refer to J. Chem. Phys. 2023, 158, 164708)

10 nmol of CuInGaS₂ core, which was synthesized in the same manner as in Comparative Example 1, was added to 3.0 ml of OLA containing 0.010 mmol of Ga(DDTC)₃ and 0.030 mmol of Ga(acac)₃, and the mixed solution was stirred in a nitrogen atmosphere at 250° C. for 20 minutes. The heating temperature was immediately changed to 220° C. Next, 3.0 ml of OLA containing 0.080 mmol of Zn(OAc)₂ and 0.080 mmol of N,N′-dimethylthiourea (DMTU) was added dropwise to the 220° C. solution at a rate of 3 ml/h, and the same temperature was maintained for 20 minutes. In this way, a CuInGaS₂ quantum dot coated with Ga—Zn—S(CuInGaS₂/Ga—Zn—S) was obtained, subjected to a purification process, and then dissolved in chloroform.

### Evaluation of Luminescence Characteristics of Quantum Dot

For the CuInGaS₂ core quantum dot and the CuInGaS₂/ZnS core/shell quantum dot synthesized in Example 1, 0.2 ml of each quantum dot was dispersed in 2.8 ml of toluene in a quartz cuvette, and the maximum emission wavelength, full width at half maximum (FWHM), and quantum yield (e.g., photoluminescence quantum yield (PLQY)) of the quantum dots were measured by using a PL spectrometer and a quantum efficiency meter. Here, the wavelength of excitation light was 450 nm.

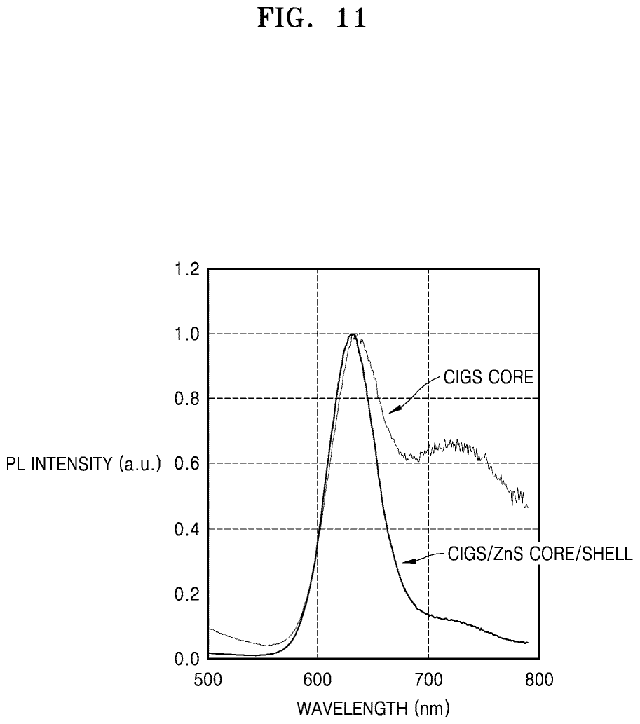

FIG. 11 is a graph showing a photoluminescence spectrum of a quantum dot of Example 1. Specifically, FIG. 11 shows photoluminescence spectra of the CuInGaS₂ (CIGS) core quantum dot and the CuInGaS₂/ZnS (CIGS/ZnS) core/shell quantum dot of Example 1. The maximum emission wavelength of photoluminescence, FWHM, and PLQY of the quantum dots of Comparative Examples 1 to 3 and Example 1 are summarized in Table 1. For the photoluminescence spectra and PLQY of Comparative Examples 1 to 3, a reference was made from J. Chem. Phys. 2023, 158, 164708.

Referring to Table 1, the CIGS/ZnS quantum dot, the CIGS/GaS quantum dot, and the CIGS/GaZnS quantum dot of Comparative Examples 1 to 3 had a wide FWHM of the photoluminescence spectra in a range of about 70 nm to about 160 nm. Meanwhile, referring to FIG. 11 and Table 1, it was confirmed that a FWHM of the photoluminescence spectrum of the CIGS/ZnS core/shell quantum dot of Example 1 was about 50 nm, showing a significantly reduced FWHM compared to the quantum dots of Comparative Examples 1 to 3.

In addition, referring to Table 1, it was shown that the PLQY of the quantum dot of Example 1 had a value that is more than twice as improved as the PLQY of the quantum dots of Comparative Examples 1 to 3.

TABLE 1

| | | Maxium | | |
|---|---|---|---|---|
| | | emission | | |
| | Structure | wavelength | FWHM | PLQY |
| Comparative | CIGS/ZnS | 649 nm | 162 nm | 30% |
| Example 1 | | | | |
| Comparative | CIGS/GaS | 671 nm | 73 nm | 27% |
| Example 2 | | | | |
| Comparative | CIGS/GaZnS | 658 nm | 74 nm | 46% |
| Example 3 | | | | |
| Example 1 | CIGS/ZnS | 632 nm | 48 nm | 92% |

### Examples 2 to 4

A CuInGaS₂/ZnS core/shell quantum dot was synthesized by the same method as in Example 1, except that, in synthesizing a CuInGaS₂/ZnS core/shell, ZnCl₂-TOP at a mole as in Table 2 was used instead of 2.0 mmol of ZnCl₂-TOP.

### Comparative Example 4

A InP/ZnSe/ZnS quantum dot emitting red light was synthesized by referring to Example 3 disclosed in KR patent application number 10-2022-0091266 (patent publication number 10-2023-0015295).

For the quantum dots of Comparative Example 4 and Examples 1 to 4, the atomic ratio of Zn/Cu and unit weight optical density (absorbance) were measured and summarized in Table 2. The atomic ratio of Zn/Cu was measured by ICP-MS, and the unit weight optical density, which is a predictor of blue light absorption efficiency, can be calculated by measuring the optical density at a wavelength of 450 nm of a quantum dot solution of known concentration in a 1 cm path length cuvette using UV-VIS equipment, and dividing the measured optical density by the concentration of the quantum dot solution (g/mL).

TABLE 2

| | | | Unit weight optical |
|---|---|---|---|
| | | Atomic ratio | density |
| | ZnCl₂-TOP | of Zn/Cu | (mL/(g · cm)) |
| Comparative | — | — | 600 |
| Example 4 | | | |
| Example 1 | 2.0 mmol | 1.9 | 2253 |
| Example 2 | 1.8 mmol | 1.7 | 2440 |
| Example 3 | 3.0 mmol | 2.7 | 1827 |
| Example 4 | 4.0 mmol | 3.8 | 1215 |

Referring to Table 2, it was confirmed that the unit weight optical density of the quantum dots of Examples 1 to 4 was more than twice as high as that of the quantum dot of Comparative Example 4, and that the unit weight optical density increased with a lower atomic ratio of Zn/Cu.

The reason why the quantum dot of aspects of the disclosure had a low atomic ratio of Zn/Cu is regarded as that Cu is contained in a high proportion in the quantum dot due to synthesis of CIGS through the Cu₂₋ₓS seed, and Zn is contained in a low proportion since the ZnS shell was formed thinly (<1 nm) on the surface of the quantum dot through additional injection of the Zn precursor. It is also considered that, as the thickness of the shell decreases, the proportion of the core that is the light-absorbing part increases, resulting in an increase in the unit weight optical density. Accordingly, a higher light absorption rate of the quantum dot according to aspects of the disclosure is expected compared to the existing quantum dots in the art.

According to the one or more aspects, a quantum dot that is prepared by synthetizing a quantum dot seed first and reacting it with a precursor to synthesize a quantum dot core of uniform shape and size may have a high optical absorption rate and a narrow full width at half maximum, and may improve efficiency of a light-emitting device including the quantum dot.

It should be understood that aspects described herein should be considered in a descriptive sense only and not for purposes of limitation. Descriptions of features within each aspect should typically be considered as available for other similar features in other aspects. While one or more aspects have been described with reference to the figures, it will be understood by those of ordinary skill in the art that various changes in form and details may be made therein without departing from the spirit and scope as defined by the following claims.

What is claimed is:

1. A quantum dot comprising:
a core comprising copper (Cu), a Group III element, and a Group VI element; and
a shell covering the core, the shell comprising zinc (Zn) and a Group VI element,
wherein an atomic ratio of Zn/Cu is from about 1 to about 4.

2. The quantum dot of claim 1, wherein the Group VI element comprises sulfur (S), selenium (Se), tellurium (Te), or any combination thereof.

3. The quantum dot of claim 1, wherein the Group III element comprises aluminum (Al), gallium (Ga), indium (In), thallium (Tl), or any combination thereof.

4. The quantum dot of claim 1, wherein the core comprises Cu, In, Ga, and S.

5. The quantum dot of claim 1, further comprising an intermediate shell comprising a Group III element and a Group VI element, wherein the intermediate shell is between the core and the shell, and wherein a composition of the intermediate shell is different from a composition of the core.

6. The quantum dot of claim 1, wherein a diameter of the core is in a range from about 1 nm to about 10 nm, and a thickness of the shell is from about 0.1 nm to about 2 nm.

7. The quantum dot of claim 1, wherein a full width at half maximum of a photoluminescence spectrum of the quantum dot is 50 nm or less.

8. The quantum dot of claim 1, wherein the quantum dot is a CuInGaS₂/ZnS core/shell quantum dot.

9. An electronic apparatus comprising:
a light source configured to emit light in a path; and
a color conversion member in the path of the light emitted from the light source,
wherein the color conversion member comprises the quantum dot of claim 1.

10. Electronic equipment comprising the electronic apparatus of claim 9.

11. The electronic equipment of claim 10, wherein the electronic equipment is one of a flat panel display, a curved display, a computer monitor, a medical monitor, a television, an advertisement board, an indoor lightening, an outdoor lighting, a signaling light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall including multiple displays tiled together, a theater or stadium screen, a phototherapy device, or a signboard.

12. A method of preparing a quantum dot, the method comprising:
synthesizing a seed comprising copper (Cu) and a Group VI element;
synthesizing a core by reacting the seed and a precursor of a Group III element; and
forming a shell on the core by reacting a solution of the core and a zinc (Zn) precursor.

13. The method of claim 12, wherein the Group VI element comprises sulfur (S), selenium (Se), tellurium (Te), or any combination thereof.

14. The method of claim 12, wherein the Group III element comprises aluminum (Al), gallium (Ga), indium (In), thallium (Tl), or any combination thereof.

15. The method of claim 12, wherein the seed is Cu₂₋ₓS, wherein 0≤x≤1.5.

16. The method of claim 12, wherein the core comprises Cu, In, Ga, and S.

17. The method of claim 12, wherein the reacting the seed and the precursor of the Group III element occurs in the solution of the core.

18. The method of claim 12, wherein a diameter of the core is from about 1 nm to about 10 nm.

19. The method of claim 12, wherein a thickness of the shell is from about 0.1 nm to about 2 nm.

20. The method of claim 12, wherein an atomic ratio of Zn/Cu in the quantum dot is from about 1 to about 4.
